(19) United States
(12) Patent Application Publication
(10) Pub. No.: US 2025/0113630 A1
(43) Pub. Date: Apr. 3, 2025

(54) SEMICONDUCTOR DEVICE AND IMAGING DEVICE

(71) Applicant: SONY SEMICONDUCTOR SOLUTIONS CORPORATION, KANAGAWA (JP)

(72) Inventor: NAOHIKO KIMIZUKA, KANAGAWA (JP)

(21) Appl. No.: 18/727,256

(22) PCT Filed: Dec. 6, 2022
(86) PCT No.: PCT/JP2022/044995

§ 371 Date: Jul. 8, 2024

(30) Foreign Application Priority Data
Jan. 18, 2022 (JP) 2022-005885

(51) Int. Cl. H10F 39/18; H10F 39/00

(52) U.S. Cl. CPC H10F 39/18; H10F 39/80373; H10F 39/807

(57) ABSTRACT

A semiconductor device capable of reducing a substrate bias effect and an imaging device using the semiconductor device are provided. The semiconductor device includes a first field effect transistor provided in a semiconductor substrate. The first field effect transistor includes a semiconductor region in which a channel is formed, a gate electrode that covers the semiconductor region, a gate insulating film disposed between the semiconductor region and the gate electrode, an n-type source region provided in the semiconductor substrate, and an n-type drain region provided in the semiconductor substrate. The semiconductor region includes an upper surface, a first side surface located on one side of the upper surface in a gate width direction of the gate electrode, and a second side surface located on the other side of the upper surface in the gate width direction. The gate electrode includes a first portion facing the upper surface across the gate insulating film, a second portion facing the first side surface across the gate insulating film, and a third portion facing the second side surface across the gate insulating film. A conductivity type of the semiconductor region is n-type.

### TECHNICAL FIELD

The present disclosure relates to a semiconductor device and an imaging device.

### BACKGROUND ART

As a semiconductor device used for a complementary metal oxide semiconductor (CMOS) image sensor, a non-planar transistor having a vertical gate electrode and a channel is known (see, for example, Patent Document 1).

### CITATION LIST

### Patent Document

Patent Document 1: Japanese Patent Application Laid-Open No. 2006-121093

### SUMMARY OF THE INVENTION

### Problems to be Solved by the Invention

In a non-planar transistor, it is desired to reduce a substrate bias effect.

The present disclosure has been made in view of such a circumstance, and an object thereof is to provide a semiconductor device capable of reducing the substrate bias effect and an imaging device using the semiconductor device.

### Solutions to Problems

A semiconductor device according to one aspect of the present disclosure includes a semiconductor substrate and a first field effect transistor provided on a first principal plane side of the semiconductor substrate. The first field effect transistor includes a semiconductor region in which a channel is formed, a gate electrode that covers the semiconductor region, a gate insulating film disposed between the semiconductor region and the gate electrode, an n-type source region provided in the semiconductor substrate, and an n-type drain region provided in the semiconductor substrate. The semiconductor region includes an upper surface, a first side surface located on one side of the upper surface in a gate width direction of the gate electrode, and a second side surface located on the other side of the upper surface in the gate width direction. The gate electrode includes a first portion facing the upper surface across the gate insulating film, a second portion facing the first side surface across the gate insulating film, and a third portion facing the second side surface across the gate insulating film. A conductivity type of the semiconductor region is n-type.

According to the above aspect, formation of a depletion layer can be prevented in the semiconductor region (that is, a Fin portion) where the channel of the first field effect transistor is formed. Therefore, even if a potential of the semiconductor substrate (substrate potential) changes, a value of a threshold voltage of the first field effect transistor can be made substantially constant, and a substrate bias effect can be reduced.

An imaging device according to one aspect of the present disclosure includes a photoelectric conversion element and a semiconductor device for reading a charge photoelectrically converted by the photoelectric conversion element. The semiconductor device includes a semiconductor substrate and a first field effect transistor provided on a first principal plane side of the semiconductor substrate. The first field effect transistor includes a semiconductor region in which a channel is formed, a gate electrode that covers the semiconductor region, a gate insulating film disposed between the semiconductor region and the gate electrode, an n-type source region provided in the semiconductor substrate, and an n-type drain region provided in the semiconductor substrate. The semiconductor region includes an upper surface, a first side surface located on one side of the upper surface in a gate width direction of the gate electrode, and a second side surface located on the other side of the upper surface in the gate width direction. The gate electrode includes a first portion facing the upper surface across the gate insulating film, a second portion facing the first side surface across the gate insulating film, and a third portion facing the second side surface across the gate insulating film. A conductivity type of the semiconductor region is n-type.

According to the above aspect, the imaging device can use a semiconductor device with a reduced substrate bias effect as the semiconductor device for reading a charge photoelectrically converted by the photoelectric conversion element. Therefore, the imaging device can improve performance.

### BRIEF DESCRIPTION OF DRAWINGS

FIG. 1 is a block diagram illustrating a configuration example of an imaging device according to an embodiment of the present disclosure.

FIG. 2 is a plan view illustrating a configuration example of a semiconductor device according to the embodiment of the present disclosure.

FIG. 3 is a cross-sectional view illustrating the configuration example of the semiconductor device according to the embodiment of the present disclosure.

FIG. 4 is a cross-sectional view illustrating the configuration example of the semiconductor device according to the embodiment of the present disclosure.

FIG. 5 is a cross-sectional view illustrating the configuration example of the semiconductor device according to the embodiment of the present disclosure.

FIG. 6 is a graph schematically illustrating results of SIMS measurement of thermal diffusion of p-type impurities from a semiconductor substrate to a Fin portion in a FinFET.

FIG. 7 is a graph illustrating results of evaluating a substrate bias effect for each of a planar MOSFET and a FinFET.

FIG. 8 is a diagram schematically illustrating electron charges in a semiconductor.

FIG. 9 is a diagram illustrating results of evaluating a relationship between a Fin width and Vth in a case where a gate length is L1 and a relationship between the Fin width and the Vth in a case where the gate length is L2, for an n-type FinFET in an accumulation mode.

FIG. 10 is a cross-sectional view illustrating a configuration of a semiconductor device according to a modification of the embodiment of the present disclosure.

### MODE FOR CARRYING OUT THE INVENTION

Hereinafter, embodiments of the present disclosure will be described with reference to the drawings. In the illustration of the drawings referred to in the following description, the same or similar portions are denoted by the same or similar reference signs. It should be noted that the drawings are schematic, and a relationship between a thickness and a planar dimension, a ratio of the thicknesses between the respective layers, and the like are different from actual ones. Therefore, specific thicknesses and dimensions should be determined in consideration of the following description. Furthermore, it goes without saying that dimensional relationships and ratios are partly different between the drawings.

Definition of directions such as upward and downward directions in the following description is merely the definition for convenience of description, and does not limit the technical idea of the present disclosure. For example, it goes without saying that when a target is rotated by 90° and observed, the upward and downward directions are converted into rightward and leftward directions, and when the target is rotated by 180° and observed, the upward and downward directions are inverted.

In the following description, there is a case where the direction is described using terms such as an X-axis direction, a Y-axis direction, and a Z-axis direction. For example, the X-axis direction and the Y-axis direction are directions parallel to an upper surface 10a of a semiconductor region 41. The X-axis direction and the Y-axis direction are also referred to as horizontal directions. The Z-axis direction is a direction perpendicular to the upper surface 10a of the semiconductor region 41. The Z-axis direction is also referred to as a depth direction. The X-axis direction, the Y-axis direction, and the Z-axis direction are orthogonal to one another.

In the following description, “+” added to “p” or “n” indicating a conductivity type of a semiconductor means that an impurity concentration is relatively higher than that of a semiconductor to which “+” is not added. However, even in the semiconductors to which the same p and p (or n and n) are added, it does not mean that the impurity concentrations of the semiconductors are exactly the same.

### (Overall Configuration Example of Imaging Device)

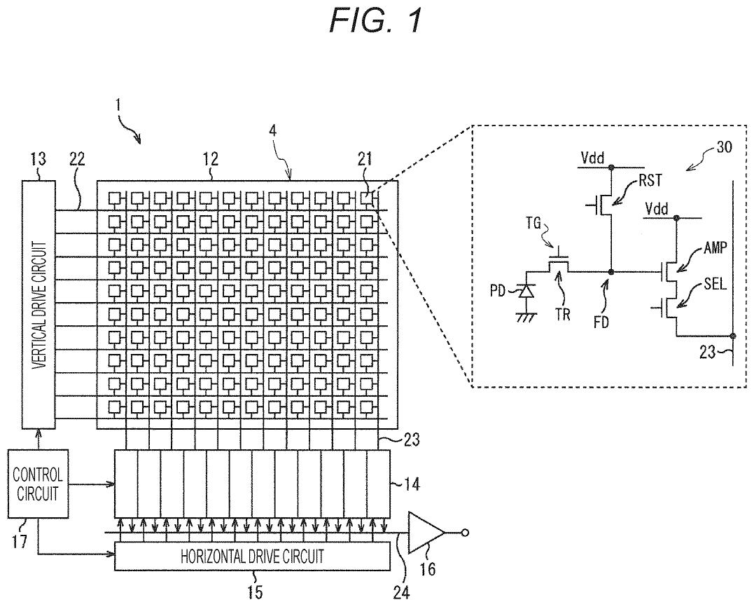

FIG. 1 is a block diagram illustrating a configuration example of an imaging device 1 according to an embodiment of the present disclosure. As illustrated in FIG. 1, the imaging device 1 includes a semiconductor substrate 4, a pixel region 12 provided on the semiconductor substrate 4, a vertical drive circuit 13, a column signal processing circuit 14, a horizontal drive circuit 15, an output circuit 16, and a control circuit 17. The vertical drive circuit 13, the column signal processing circuit 14, the horizontal drive circuit 15, the output circuit 16, and the control circuit 17 may be provided on the semiconductor substrate 4, or may be provided on a second semiconductor substrate disposed on a front surface side of the (first) semiconductor substrate 4 via a multilayer wiring layer (all not illustrated) including a wiring layer and an interlayer insulating film.

The pixel region 12 is a light-receiving region that receives light condensed by an optical system (not illustrated), and includes a plurality of pixels 21. The plurality of pixels 21 is arranged in a matrix. The plurality of pixels 21 is connected to the vertical drive circuit 13 for every row via horizontal signal lines 22, and is connected to the column signal processing circuit 14 for every column via vertical signal lines 23. The plurality of pixels 21 outputs pixel signals at levels corresponding to amounts of light respectively received. An image of an object is constructed from these pixel signals.

The vertical drive circuit 13 sequentially supplies drive signals for driving (such as transferring, selecting, and resetting) the respective pixels 21 for every row of the plurality of pixels 21 to the pixels 21 via the horizontal signal lines 22. By performing correlated double sampling (CDS) processing for the pixel signals output from the plurality of pixels 21 via the vertical signal lines 23, the column signal processing circuit 14 performs analog-to-signal (AD) conversion for the pixel signals and removes reset noise.

The horizontal drive circuit 15 sequentially supplies, to the column signal processing circuit 14, drive signals for causing the column signal processing circuit 14 to output pixel signals to a data output signal line 24 for every column of the plurality of pixels 21. The output circuit 16 amplifies the pixel signals supplied from the column signal processing circuit 14 via the data output signal line 24 at timing according to the drive signals of the horizontal drive circuit 15, and outputs the amplified pixel signals to a signal processing circuit of a subsequent stage. The control circuit 17 controls driving of each block inside the imaging device 1. For example, the control circuit 17 generates a clock signal according to a drive cycle of each block and supplies the clock signals to the respective blocks.

The pixel 21 includes a photodiode PD (an example of a “photoelectric conversion element” of the present disclosure), a transfer transistor TR, a floating diffusion FD, an amplification transistor AMP, a selection transistor SEL, and a reset transistor RST. The transfer transistor TR, the floating diffusion FD, the amplification transistor AMP, the selection transistor SEL, and the reset transistor RST constitute a read circuit 30 that reads a charge (pixel signal) photoelectrically converted by the photodiode PD.

The photodiode PD is a photoelectric conversion unit that converts incident visible light into a charge by photoelectric conversion and stores the charge, and has an anode terminal grounded and a cathode terminal connected to the transfer transistor TR. A transfer signal is supplied from the vertical drive circuit 13 to a gate electrode TG (hereinafter also referred to as a transfer gate) of the transfer transistor TR. The transfer transistor TR is driven in accordance with the transfer signal supplied to the transfer gate TG. When the transfer transistor TR is turned on, the charge accumulated in the photodiode PD is transferred to the floating diffusion FD.

The floating diffusion FD is a floating diffusion region having a predetermined storage capacitance connected to the gate electrode of the amplification transistor AMP, and temporarily stores the charge transferred from the photodiode PD. The amplification transistor AMP outputs the pixel signal of a level (that is, a potential of the floating diffusion FD) corresponding to the charge accumulated in the floating diffusion FD to the vertical signal line 23 (an example of a “signal line” of the present disclosure) via the selection transistor SEL. That is, with the configuration in which the floating diffusion ED is connected to the gate electrode of the amplification transistor AMP, the floating diffusion FD and the amplification transistor AMP function as a conversion unit that amplifies the charge generated in the photodiode PD and converts the charge into the pixel signal at the level corresponding to the charge.

The selection transistor SEL is driven in accordance with a selection signal supplied from the vertical drive circuit 13. When the selection transistor SEL is turned on, the pixel signal output from the amplification transistor AMP can be output to the vertical signal line 23. The reset transistor RST is driven in accordance with a reset signal supplied from the vertical drive circuit 13. When the reset transistor RST is turned on, the charge accumulated in the floating diffusion FD is discharged to a power supply line Vdd, and the floating diffusion FD is reset.

### (Configuration Example of Semiconductor Device)

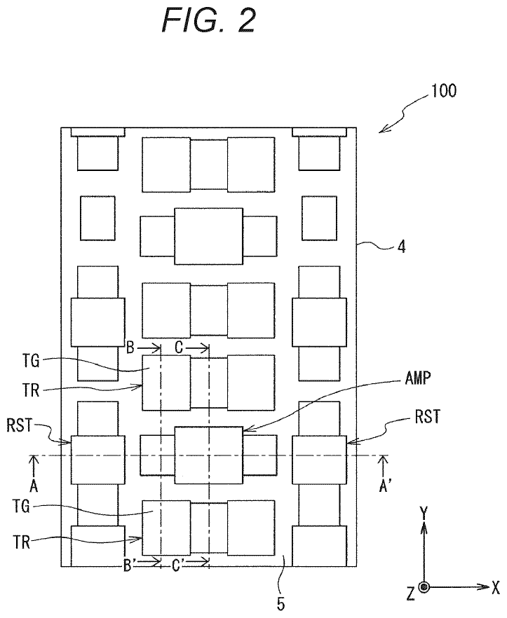

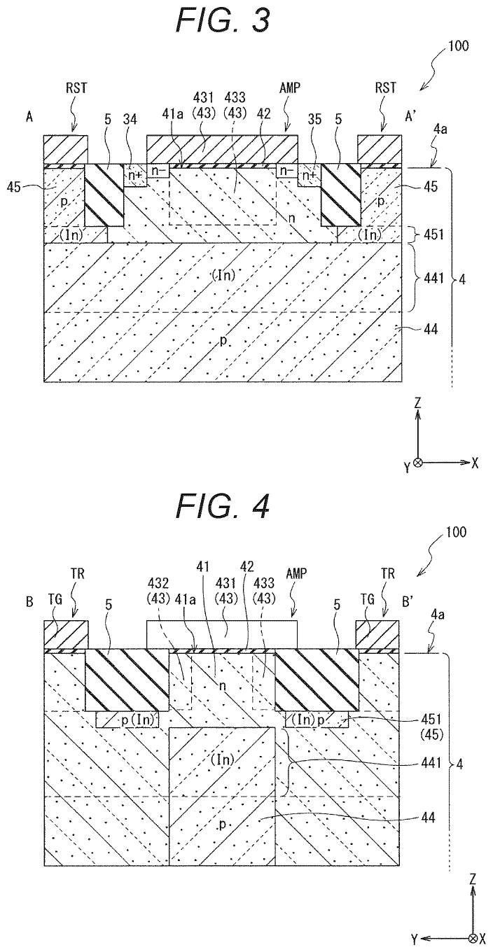

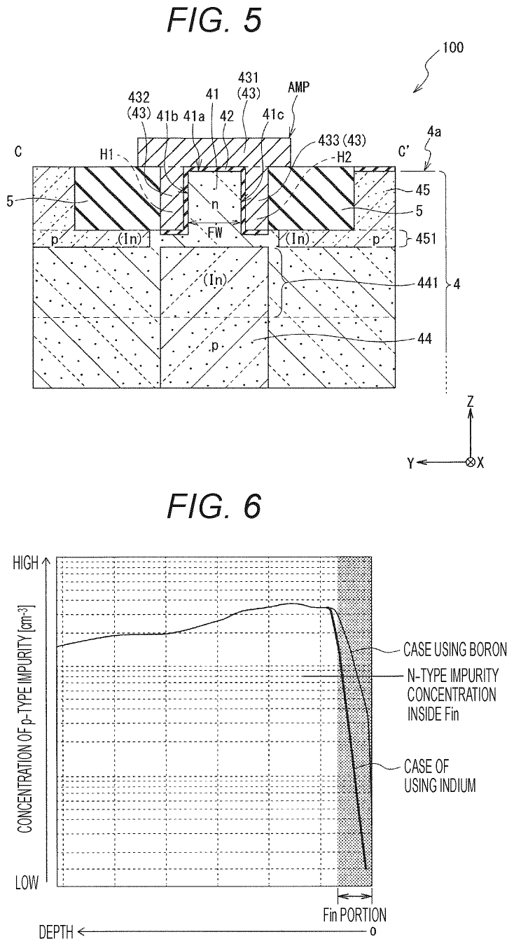

FIG. 2 is a plan view illustrating a configuration example of a semiconductor device 100 according to the embodiment of the present disclosure. FIGS. 3 to 5 are cross-sectional views illustrating the configuration example of the semiconductor device 100 according to the embodiment of the present disclosure. FIG. 3 illustrates a cross section of the semiconductor device 100 illustrated in FIG. 2 taken along line A-A′. FIG. 4 illustrates a cross section of the semiconductor device 100 illustrated in FIG. 2 taken along line B-B′. FIG. 5 illustrates a cross section of the semiconductor device 100 illustrated in FIG. 2 taken along line C-C′.

The semiconductor device 100 is a device for reading the charge (pixel signal) photoelectrically converted by the photodiode PD (see FIG. 1), and includes at least a part of the read circuit 30 (see FIG. 1). For example, as illustrated in FIGS. 2 to 5, the semiconductor device 100 includes the n-type semiconductor substrate 4, the transfer transistor TR provided on the semiconductor substrate 4, the amplification transistor AMP (an example of a “first field effect transistor” of the present disclosure), the reset transistor RST (an example of a “second field effect transistor” of the present disclosure), and an element isolation layer 5 provided on a front surface 4a side of the semiconductor substrate 4.

The semiconductor substrate 4 is configured by, for example, single crystal silicon, and is doped with an n-type impurity such as phosphorus or arsenic to form an n-type semiconductor. The semiconductor substrate 4 has the front surface 4a (an example of a “first principal plane” of the present disclosure) and a back surface located on an opposite side of the front surface 4a. The amplification transistor AMP, the reset transistor RST, and the transfer transistor TR are provided on the front surface 4a side of the semiconductor substrate 4. The element isolation layer 5 is an insulating film for electrically isolating elements adjacent to each other in the horizontal direction, and is configured by, for example, trench isolation. This trench isolation has, for example, a structure in which an insulating film such as a silicon oxide film (SiO₂ film) is embedded in a trench opened on the front surface 4a side of the semiconductor substrate 4.

The amplification transistor AMP is an n-type metal oxide semiconductor field effect transistor (MOSFET) in an accumulation mode. The n-type MOSFET in the accumulation mode is an n-type MOSFET that accumulates electrons in an n-type semiconductor region by applying a voltage to the gate electrode and uses the electrons as a channel, and is a MOSFET in which each conductivity type of a source region, a drain region, and a semiconductor region in which a channel is formed is n-type. The amplification transistor AMP is an n-type MOSFET in the accumulation mode, and is a FinFET as will be described below. The amplification transistor AMP includes the n-type semiconductor region 41 in which a channel is formed, a gate insulating film 42, a gate electrode 43, and an n-type source region 34 and an n-type drain region 35 provided in the semiconductor substrate 4.

The semiconductor region 41 is a part of the semiconductor substrate 4, for example, and is configured by single crystal silicon. The semiconductor region 41 is a portion formed by etching a part of the front surface 4a side of the semiconductor substrate 4. The conductivity type of the semiconductor region 41 is n-type. The shape of the semiconductor region 41 is, for example, a fin (Fin) shape. The semiconductor region 41 has a shape that is long in the X-axis direction and short in the Y-axis direction.

The length (width FW) of the semiconductor region 41 in the Y-axis direction is, for example, 50 nm or more and 200 nm or less, favorably 50 nm or more and 100 nm or less, and more favorably 50 nm or more and 70 nm or less. Therefore, this facilitates suppression of a short-channel effect to be described below with reference to FIG. 8.

In the Y-axis direction, a first trench H1 is provided on one side in the semiconductor region 41, and a second trench H2 is provided on the other side in the semiconductor region 41. The first trench H1 and the second trench H2 are opened to the front surface 4a side of the semiconductor substrate 4.

The gate insulating film 42 is provided so as to continuously cover an upper surface 41a of the semiconductor region 41, a first side surface 41b and a second side surface 41c of the semiconductor region 41, and a bottom surface of the first trench H1 and a bottom surface of the second trench H2. The first side surface 41b of the semiconductor region 41 is located on one side of the upper surface 41a in the Y-axis direction. The second side surface 41c of the semiconductor region 41 is located on the other side of the upper surface 41a in the Y-axis direction. The gate insulating film 42 is configured by, for example, a SiO₂ film.

The gate electrode 43 covers the semiconductor region 41 via the gate insulating film 42. For example, the gate electrode 43 includes a first portion 431 facing the upper surface 10a of the semiconductor region 41 across the gate insulating film 42, a second portion 432 facing the first side surface 10b of the semiconductor region 41 across the gate insulating film 42, and a third portion 433 facing the second side surface 10c of the semiconductor region 41 across the gate insulating film 42. The second portion 432 and the third portion 433 are connected to a lower surface of the first portion 431.

The second portion 432 of the gate electrode 43 is disposed in the first trench H1. The third portion 433 of the gate electrode 43 is disposed in the second trench H2. The semiconductor region 41 is sandwiched in the Y-axis direction by the second portion 432 disposed in the first trench H1 and the third portion 433 disposed in the second trench H2.

Therefore, the gate electrode 43 can simultaneously apply the gate voltage to the upper surface 10a, the first side surface 10b, and the second side surface 10c of the semiconductor region 41. That is, the gate electrode 43 can simultaneously apply the gate voltage to the semiconductor region 41 from three directions including an upper side and left and right sides. Therefore, the gate electrode 43 can completely deplete the semiconductor region 41. Note that the gate electrode 43 is configured by, for example, a polysilicon (Poly-Si) film doped with impurities.

The source region 34 is provided on the front surface 4a of the semiconductor substrate 4 and in the vicinity thereof. The source region 34 is an n-type impurity region, and includes an n+ region and an n-region located on a side closer to the semiconductor region 41 than the n+ region. In the X-axis direction, the source region 34 is connected to one side of the semiconductor region 41.

The drain region 35 is provided on the front surface 4a of the semiconductor substrate 4 and in the vicinity thereof. The drain region 35 is an n-type impurity region, and includes an n+ region and an n-region located on a side closer to the semiconductor region 41 than the n+ region. In the X-axis direction, the drain region 35 is connected to the other side of the semiconductor region 41.

The amplification transistor AMP according to the embodiment of the present disclosure may be referred to as a MOS transistor having a dug gate structure from a shape in which the second portion 432 and the third portion 433 of the gate electrode 43 are arranged in the first trench H1 and the second trench H2, respectively. Alternatively, since the semiconductor region 41 has a fin shape, the amplification transistor AMP may be referred to as a fin field effect transistor (FinFET). Alternatively, the amplification transistor AMP may be called a dug FinFET from the above two shapes.

As illustrated in FIGS. 3 to 5, the semiconductor device 100 further includes a p-type region provided in the semiconductor substrate 4 and located around the amplification transistor AMP. For example, the semiconductor device 100 includes a first p-type region 44 provided immediately below the semiconductor region 41 as the above p-type region. The first p-type region 44 is a p-type well region located in a region (that is, inside the substrate) at a certain depth or more from the front surface 4a of the semiconductor substrate 4.

At least an upper region 441 of the first p-type region 44 contains indium (In), not boron (B), as a p-type impurity. In the first p-type region 44, the upper region 441 is located on a side close to the front surface 4a of the semiconductor substrate 4. In the first p-type region 44, the entire region including the upper region 441 may contain indium (In), not boron (B), as the p-type impurity. The first p-type region 44 can be formed by, for example, multistage ion implantation of indium (In) under a plurality of implantation energy conditions.

The semiconductor device 100 includes a second p-type region 45 provided on the front surface 4a side of the semiconductor substrate 4 as the above p-type region. The second p-type region 45 is a p-type well region located on the opposite side of the amplification transistor AMP across the element isolation layer 5. For example, the channel of the reset transistor RST is formed in the second p-type region 45. A lower region 451 of the second p-type region 45 extends below the element isolation layer 5. In the second p-type region 45, the lower region 451 is located on a side far from the front surface 4a of the semiconductor substrate 4.

At least the lower region 451 of the second p-type region 45 contains indium (In), not boron (B), as the p-type impurity. In the second p-type region 45, the entire region including the lower region 451 may contain indium (In), not boron (B), as the p-type impurity. The second p-type region 45 can be formed by, for example, multistage ion implantation of indium (In) under a plurality of implantation energy conditions.

### (Suppression of Thermal Diffusion)

Indium (In) has a smaller diffusion coefficient than boron (B). Therefore, thermal diffusion (that is, diffusion by thermal history) of the p-type impurities can be suppressed from the upper region 441 of the first p-type region 44 to the semiconductor region 41. Furthermore, the thermal diffusion of the p-type impurities from the lower region 451 of the second p-type region 45 to the semiconductor region 41 can be suppressed. Therefore, the conductivity type of the semiconductor region 41 can be easily maintained to be n-type.

FIG. 6 is a graph schematically illustrating results of measuring the thermal diffusion of the p-type impurities (boron (B) and indium (In)) from the semiconductor substrate to the Fin-shaped semiconductor region (hereinafter, also referred to as a Fin portion) by secondary ion mass spectrometry (SIMS) in the FinFET. The horizontal axis in FIG. 6 represents a depth [μm] from the front surface of the semiconductor substrate. The left end of the horizontal axis has the depth of 0 (that is, it is the front surface of the semiconductor substrate and is also the upper surface of the Fin portion), and the depth increases from the left to right. In FIG. 6, the vertical axis represents the concentration [cm⁻³] of the p-type impurity.

In this measurement, boron (B) and indium (In) were ion-implanted as the p-type impurities in the depth direction from the front surface of the semiconductor substrate under the same conditions (same dose and same implantation energy), and next, heat treatment for activating the p-type impurities was performed, and thereafter, the p-type impurity concentrations in the semiconductor substrate were measured. An implantation peak of the p-type impurities was set to a position deeper than the Fin portion.

As illustrated in FIG. 6, the concentration of the p-type impurity in the Fin portion is lower in indium (In) than in boron (B). This means that the heat diffusion from the inside of the semiconductor substrate to the Fin portion is smaller in indium (In) than in boron (B).

### (Reduction of Substrate Bias Effect and Improvement of Transconductance gm)

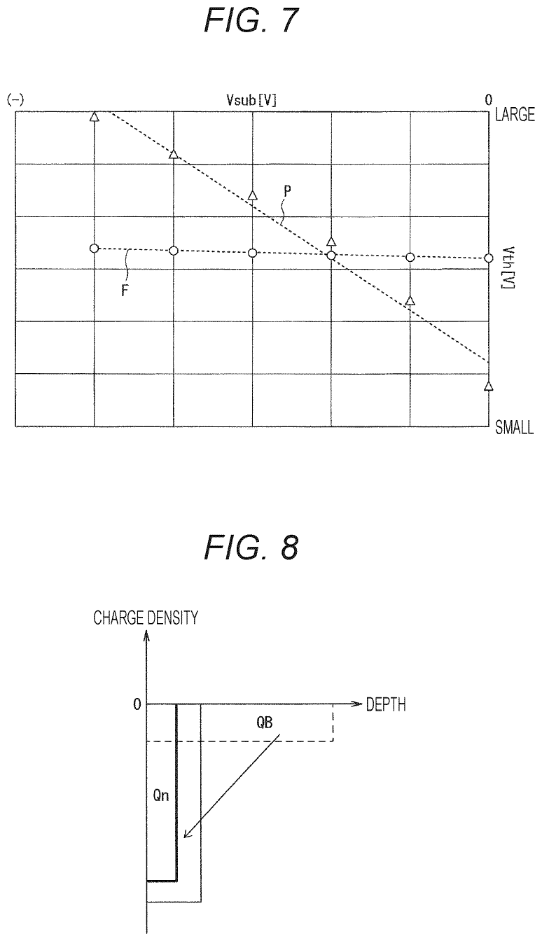

FIG. 7 is a graph illustrating results of evaluating the substrate bias effect for each of a planar MOSFET and a FinFET. The horizontal axis in FIG. 7 represents a potential (hereinafter also referred to as a substrate potential) Vsub [V] of the semiconductor substrate. In FIG. 7, the vertical axis represents a threshold voltage Vth of the MOSFET. Furthermore, in FIG. 7, a straight line P is a straight line obtained by approximating a measured value of the planar MOSFET by the least squares method. A straight line F is a straight line obtained by approximating the measured value of the n-type FinFET in the accumulation mode by the least squares method.

The planar MOSFET used in this evaluation is an n-type MOSFET having an inversion layer as a channel.

As illustrated in FIG. 7, in the planar MOSFET, when the substrate potential changes, the threshold voltage Vth also changes (that is, it has the substrate bias effect). Although not illustrated in FIG. 7, an n-type FinFET (a Fin portion is p-type) having an inversion layer as a channel also has the substrate bias effect although the degree is relaxed because the channel has a Fin shape.

In contrast, in the n-type FinFET in the accumulation mode, the threshold voltage Vth is substantially constant even when the substrate potential changes (that is, there is almost no substrate bias effect). This is because, in addition to the effect that the channel has a Fin shape and is surrounded by the gate electrode, electrons accumulated in the n-type semiconductor substrate are used as a channel, and the depletion layer is not formed in the Fin portion.

FIG. 8 is a diagram schematically illustrating electron charges in a semiconductor. The horizontal axis in FIG. 8 represents the depth direction of a semiconductor layer, and the vertical axis represents electron charge density. Furthermore, the following expression (1) is an expression indicating an electron charge per unit area of the semiconductor. In the n-type FinFET in the accumulation mode, the depletion layer is not formed. Therefore, in FIG. 8 and the following expression (1), an electron charge QB of the depletion layer can be reduced. An electron charge Qn serving as a bearer of on-current can be increased by the reduced electron charge QB of the depletion layer. [Math. 1]

$${Q}_{S} = {\int }_{0}^{∞} ρ dx = {Q}_{n} + {Q}_{B} \qquad ( 1 )$$

In the expression (1), Qs is the electron charge per unit area of the semiconductor, Qn is the electron charge of an electron inductive layer serving as the bearer of on-current, and QB is the electron charge of the depletion layer.

As described above, in the n-type FinFET in the accumulation mode, the substrate bias effect can be reduced, and the electron charge Qn serving as the bearer of on-current can be increased, so that transconductance gm can be improved. By using the n-type FinFET in the accumulation mode for the amplification transistor AMP, the transconductance gm of the amplification transistor AMP can be improved, and a gain can be improved.

### (Suppression of Short Channel Effect)

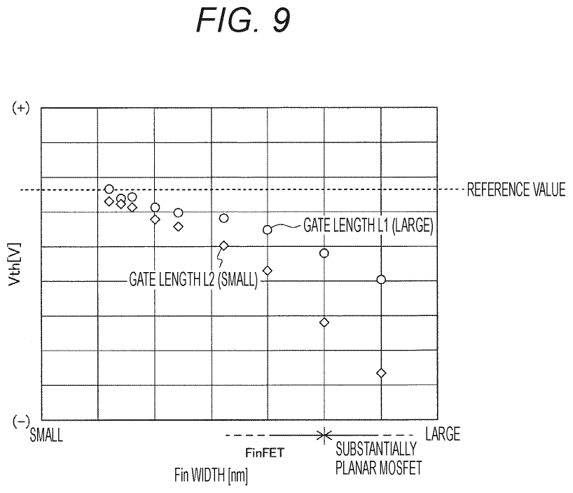

FIG. 9 is a diagram illustrating results of evaluating a relationship between a Fin width and Vth in a case where a gate length is L1 and a relationship between the Fin width and the Vth in a case where the gate length is L2, for the n-type FinFET in the accumulation mode. L1>L2. Furthermore, the Fin width is, for example, a length (width FW) in the Y-axis direction of the semiconductor region 41 illustrated in FIG. 5. The horizontal axis in FIG. 9 represents the Fin width, and the vertical axis represents Vth. Note that the FinFET in the region where the Fin width is sufficiently large in FIG. 9 can be regarded as substantially a planar MOSFET because the Fin portion is not completely depleted.

In FIG. 9, Vth when the gate length is L1 and the Fin width is minimum is set as a reference value. It can be said that the larger the difference from the reference value, the larger the shorter channel effect. From FIG. 9, it was confirmed that the short channel effect can be suppressed by using the FinFET instead of the planar MOSFET even in the case where a channel is formed in the n-type semiconductor (that is, in the accumulation mode). Furthermore, it was confirmed that the shorter the Fin width, the more the short channel effect can be suppressed.

### Effect of Embodiment

As described above, the semiconductor device 100 according to the embodiment of the present disclosure includes the semiconductor substrate 4 and the amplification transistor AMP provided on the front surface 4a side of the semiconductor substrate 4. The amplification transistor AMP includes the semiconductor region (Fin portion) 41 in which a channel is formed, the gate electrode 43 covering the semiconductor region 41, the gate insulating film 42 disposed between the semiconductor region 41 and the gate electrode 43, the n-type source region 34 provided in the semiconductor substrate 4, and the n-type drain region 35 provided in the semiconductor substrate 4. The semiconductor region 41 includes the upper surface 41a, the first side surface 41b located on one side of the upper surface 41a in the gate width direction of the gate electrode 43, and the second side surface 41c located on the other side of the upper surface 41a in the gate width direction. The gate electrode 43 includes the first portion 431 facing the upper surface 41a across the gate insulating film 42, the second portion 432 facing the first side surface 41b across the gate insulating film 42, and the third portion 433 facing the second side surface 41c across the gate insulating film 42. The conductivity type of the semiconductor region 41 is n-type.

According to this configuration, formation of a depletion layer can be prevented in the semiconductor region (that is, the Fin portion) 41 where the channel of the amplification transistor AMP is formed. Therefore, for example, as illustrated in FIG. 7, even if the potential (substrate potential) Vsub of the semiconductor substrate 4 changes, the value of the threshold voltage Vth of the amplification transistor AMP can be made substantially constant, and the substrate bias effect can be reduced.

Since the depletion layer is not formed in the semiconductor region 41, the electron charge QB of the depletion layer can be reduced as illustrated in FIG. 8, and the electron charge Qn serving as the bearer of on-current can be increased by the reduced electron charge QB.

As described above, the substrate bias effect can be reduced, and the electron charge Qn serving as the bearer of the on-current can be increased, so that the transconductance gm of the amplification transistor AMP can be improved. Therefore, the gain of the amplification transistor AMP can be improved.

As illustrated in FIG. 9, the amplification transistor AMP is the n-type FinFET in the accumulation mode using an accumulation layer as a channel. Therefore, as illustrated in FIG. 9, the short channel effect can be suppressed.

In general, since FinFETs are easy to geometrically increase the channel width (W) as compared with planar transistors, noise components can be suppressed (here, the noise indicates random noise such as thermal noise or 1/f noise). In this FinFET, when the conductivity type of the semiconductor region (Fin portion) in which the channel is formed is n-type, the noise is further suppressed as compared with the case of p-type. In the embodiment of the present disclosure, the conductivity type of the semiconductor region 41 (Fin portion) in which the channel of the amplification transistor is formed is n-type. Therefore, the amplification transistor AMP can suppress the noise.

Also in the planar type transistor, a similar effect is observed by using electrons accumulated in an n-type conductor as carriers, but controllability of a threshold voltage is generally deteriorated due to the short channel effect. In the case where the channel has the Fin shape as in the embodiment of the present disclosure, this drawback can be avoided.

Furthermore, the semiconductor device 100 according to the embodiment of the present disclosure further includes the p-type region provided in the semiconductor substrate 4 and located around the amplification transistor AMP. This p-type region contains indium as the p-type impurity. For example, the p-type region includes the first p-type region 44 located immediately below the amplification transistor AMP and the second p-type region 45 adjacent to the amplification transistor AMP via the element isolation layer 5. At least the upper region 441 of the first p-type region 44 and at least the lower region 451 of the second p-type region 45 contain indium (In) as the p-type impurity, and more favorably contain only indium (In) as the p-type impurity.

According to this configuration, thermal diffusion of the p-type impurities from the p-type region located around the amplification transistor AMP to the semiconductor region (Fin portion) 41 can be suppressed. Therefore, the conductivity type of the semiconductor region 41 can be easily maintained to be n-type.

The imaging device 1 according to the embodiment of the present disclosure includes the photodiode PD and the semiconductor device 100 for reading the charge photoelectrically converted by the photodiode PD. As described above, the amplification transistor AMP included in the semiconductor device 100 can reduce the substrate bias effect and improve characteristics such as the transconductance gm. The imaging device 1 can improve charge readout performance by using the amplification transistor AMP with improved transistor characteristics for the read circuit 30.

### (Modification)

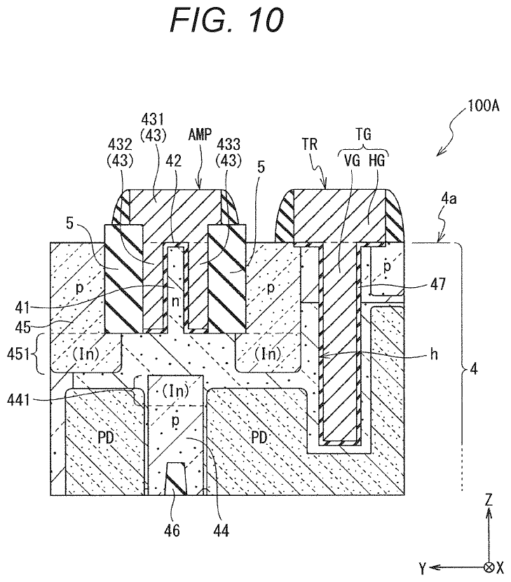

FIG. 10 is a cross-sectional view illustrating a configuration of a semiconductor device 100A according to a modification of the embodiment of the present disclosure. As illustrated in FIG. 10, in the embodiment of the present disclosure, the photodiode PD may be provided on the back surface side of the semiconductor substrate 4. In the embodiment of the present disclosure, the back-illuminated imaging device 1 (see the drawing) may be configured by including this semiconductor substrate 4.

As illustrated in FIG. 10, the transfer transistor TR may be provided with an opening h that opens to the front surface 4a side and is adjacent to the photodiode PD in the semiconductor substrate 4. The gate electrode TG may include a vertical gate electrode VG disposed in the opening h via the gate insulating film 47 and extending in a longitudinal direction, and a horizontal gate electrode HG extending in a lateral direction on the gate insulating film 47 and connected to the vertical gate electrode VG. The longitudinal direction is the depth direction from the front surface 4a (that is, the direction perpendicular to the front surface 4a) of the semiconductor substrate 4. The lateral direction is a direction orthogonal to the depth direction of the semiconductor substrate 4 (that is, the direction parallel to the front surface 4a of the semiconductor substrate 4).

As illustrated in FIG. 10, a trench isolation 46 for separating pixels (that is, adjacent photodiodes PD) may be provided on the back surface side of the semiconductor substrate 4. The trench isolation 46 may be formed in the first p-type region 44.

Even with such a configuration, the semiconductor device 100A achieves effects similar to the semiconductor device 100 illustrated in FIGS. 2 to 5, such as reduction of the substrate bias effect, improvement of the transconductance gm, and suppression of the thermal diffusion due to inclusion of indium (In) as the p-type impurity.

### OTHER EMBODIMENTS

As described above, the present disclosure is described according to the embodiment and modification thereof, but it should not be understood that the description and drawings forming a part of this disclosure limit the present disclosure. Various alternative embodiments, examples, and operation techniques will be apparent to those skilled in the art from this disclosure.

For example, in the above embodiment, the amplification transistor AMP has been exemplified as the “first field effect transistor” of the present disclosure. However, the “first field effect transistor” of the present disclosure is not limited to the amplification transistor AMP. The “first field effect transistor” may be a transistor for other purposes than amplification. Furthermore, the application of the “semiconductor device” of the present disclosure is not limited to the read circuit 30, and is also not limited to the imaging device 1. The “semiconductor device” of the present disclosure may be used in a circuit other than the read circuit 30 or an electronic device other than the imaging device 1.

As described above, it is needless to say that the present technology includes various embodiments and the like that are not described herein. At least one of various omissions, substitutions, and changes of the components may be made without departing from the gist of the above-described embodiments and modified examples. Furthermore, the effect described in the present description is illustrative only; the effect is not limited thereto and there may also be another effect.

Note that the present disclosure can also have the following configurations.

(1)

A semiconductor device including:
a semiconductor substrate; and
a first field effect transistor provided on a first principal plane side of the semiconductor substrate, in which
the first field effect transistor includes
a semiconductor region in which a channel is formed,
a gate electrode that covers the semiconductor region,
a gate insulating film disposed between the semiconductor region and the gate electrode,
an n-type source region provided in the semiconductor substrate, and
an n-type drain region provided in the semiconductor substrate,
the semiconductor region includes
an upper surface,
a first side surface located on one side of the upper surface in a gate width direction of the gate electrode, and
a second side surface located on the other side of the upper surface in the gate width direction,
the gate electrode includes
a first portion facing the upper surface across the gate insulating film,
a second portion facing the first side surface across the gate insulating film, and
a third portion facing the second side surface across the gate insulating film, and
a conductivity type of the semiconductor region is n-type.
   (2)

The semiconductor device according to (1), further including:
a p-type region provided in the semiconductor substrate and located around the first field effect transistor, in which
the p-type region contains indium as a p-type impurity.
   (3)

The semiconductor device according to (2), in which
the p-type region includes
a first p-type region located immediately below the semiconductor region.
   (4)

The semiconductor device according to (2) or (3), further including:
an element isolation layer provided on the first principal plane side of the semiconductor substrate and adjacent to the first field effect transistor, in which
the p-type region includes
a second p-type region located on an opposite side of the first field effect transistor across the element isolation layer.
   (5)

The semiconductor device according to (4), in which a part of the second p-type region extends immediately below the element isolation layer.

(6)

The semiconductor device according to (5), further including: a second field effect transistor provided in the semiconductor substrate and having a channel formed in the second p-type region.

(7)

The semiconductor device according to any one of (1) to (6), in which the conductivity type of the semiconductor substrate is n-type.

(8)

An imaging device including:
a photoelectric conversion element; and
a semiconductor device for reading a charge photoelectrically converted by the photoelectric conversion element, in which
the semiconductor device includes
a semiconductor substrate, and
a first field effect transistor provided on a first principal plane side of the semiconductor substrate,
the first field effect transistor includes
a semiconductor region in which a channel is formed,
a gate electrode that covers the semiconductor region,
a gate insulating film disposed between the semiconductor region and the gate electrode,
an n-type source region provided in the semiconductor substrate, and
an n-type drain region provided in the semiconductor substrate,
the semiconductor region includes
an upper surface,
a first side surface located on one side of the upper surface in a gate width direction of the gate electrode, and
a second side surface located on the other side of the upper surface in the gate width direction,
the gate electrode includes
a first portion facing the upper surface across the gate insulating film,
a second portion facing the first side surface across the gate insulating film, and
a third portion facing the second side surface across the gate insulating film, and
a conductivity type of the semiconductor region is n-type.
   (9)

The imaging device according to (8), in which
the semiconductor device includes
a floating diffusion configured to accumulate a charge generated by the photoelectric conversion element, and
an amplification transistor configured to output, to a signal line, a pixel signal at a level corresponding to the charge accumulated in the floating diffusion, and
the first field effect transistor is used as the amplification transistor.

### REFERENCE SIGNS LIST

1 Imaging device
4 Semiconductor substrate
4a Front surface
5 Element isolation layer
10a Upper surface
10b First side surface
10c Second side surface
12 Pixel region
13 Vertical drive circuit
14 Column signal processing circuit
15 Horizontal drive circuit
16 Output circuit
17 Control circuit
21 Pixel
22 Horizontal signal line
23 Vertical signal line
24 Data output signal line
30 Read circuit
34 Source region
35 Drain region
41 Semiconductor region (Fin portion)
41a Upper surface
41b First side surface
41c Second side surface
42 Gate insulating film
43 Gate electrode
44 First p-type region
45 Second p-type region
46 Trench Isolation
47 Gate insulating film
100, 100A Semiconductor device
431 First portion
432 Second portion
433 Third portion
441 Upper region
451 Lower region
AMP Amplification transistor
FD Floating diffusion
Fin Fin
h Opening
H1 First trench
H2 Second trench
HG Horizontal gate electrode
PD Photodiode
RST Reset transistor
SEL Selection transistor
TG Gate electrode (transfer gate)
TR Transfer transistor
Vdd Power supply line
VG Vertical gate electrode

1. A semiconductor device comprising:
a semiconductor substrate; and
a first field effect transistor provided on a first principal plane side of the semiconductor substrate, wherein
the first field effect transistor includes
a semiconductor region in which a channel is formed,
a gate electrode that covers the semiconductor region,
a gate insulating film disposed between the semiconductor region and the gate electrode,
an n-type source region provided in the semiconductor substrate, and
an n-type drain region provided in the semiconductor substrate,
the semiconductor region includes
an upper surface,
a first side surface located on one side of the upper surface in a gate width direction of the gate electrode, and
a second side surface located on the other side of the upper surface in the gate width direction,
the gate electrode includes
a first portion facing the upper surface across the gate insulating film,
a second portion facing the first side surface across the gate insulating film, and
a third portion facing the second side surface across the gate insulating film, and
a conductivity type of the semiconductor region is n-type.

2. The semiconductor device according to claim 1, further comprising:
a p-type region provided in the semiconductor substrate and located around the first field effect transistor, wherein
the p-type region contains indium as a p-type impurity.

3. The semiconductor device according to claim 2, wherein
the p-type region includes
a first p-type region located immediately below the semiconductor region.

4. The semiconductor device according to claim 2, further comprising:
an element isolation layer provided on the first principal plane side of the semiconductor substrate and adjacent to the first field effect transistor, wherein
the p-type region includes
a second p-type region located on an opposite side of the first field effect transistor across the element isolation layer.

5. The semiconductor device according to claim 4, wherein a part of the second p-type region extends immediately below the element isolation layer.

6. The semiconductor device according to claim 5, further comprising: a second field effect transistor provided in the semiconductor substrate and having a channel formed in the second p-type region.

7. The semiconductor device according to claim 1, wherein the conductivity type of the semiconductor substrate is n-type.

8. An imaging device comprising:
a photoelectric conversion element; and
a semiconductor device for reading a charge photoelectrically converted by the photoelectric conversion element, wherein
the semiconductor device includes
a semiconductor substrate, and
a first field effect transistor provided on a first principal plane side of the semiconductor substrate,
the first field effect transistor includes
a semiconductor region in which a channel is formed,
a gate electrode that covers the semiconductor region,
a gate insulating film disposed between the semiconductor region and the gate electrode,
an n-type source region provided in the semiconductor substrate, and
an n-type drain region provided in the semiconductor substrate,
the semiconductor region includes
an upper surface,
a first side surface located on one side of the upper surface in a gate width direction of the gate electrode, and
a second side surface located on the other side of the upper surface in the gate width direction,
the gate electrode includes
a first portion facing the upper surface across the gate insulating film,
a second portion facing the first side surface across the gate insulating film, and
a third portion facing the second side surface across the gate insulating film, and
a conductivity type of the semiconductor region is n-type.

9. The imaging device according to claim 8, wherein
the semiconductor device includes
a floating diffusion configured to accumulate a charge generated by the photoelectric conversion element, and
an amplification transistor configured to output, to a signal line, a pixel signal at a level corresponding to the charge accumulated in the floating diffusion, and
the first field effect transistor is used as the amplification transistor.
